(19) United States
(12) Patent Application Publication
(10) Pub. No.: US 2013/0229774 A1
(43) Pub. Date: Sep. 5, 2013

(54) ELECTRONIC DEVICE

(71) Applicant: ASUSTEK COMPUTER INC., Taipei (TW)

(72) Inventors: Ching-Hua CHEN, Taipei (TW); Shih-Kun CHOU, Taipei (TW); Yen Tse LIU, Taipei (TW); Shih-Ming LIN, Taipei (TW)

(73) Assignee: ASUSTek COMPUTER INC., Taipei (TW)

(21) Appl. No.: 13/760,645

(22) Filed: Feb. 6, 2013

(30) Foreign Application Priority Data
Mar. 2, 2012 (TW) 101107088

(51) Int. Cl. H05K 7/20

(52) U.S. Cl. CPC H05K 7/20136; H05K 7/2039
USPC 361/695; 361/704

(57) ABSTRACT

An electronic device is provided, and the electronic device includes a main body, an actuating module, a first linkage, a first casing and a thermal dissipating module. The actuating module is disposed in the main body. One side of the first linkage is connected with the actuating module. The first casing is connected with the other side of the first linkage. One side of the thermal dissipating module is disposed at the main body and the other side of the thermal dissipating module is disposed at the first casing. The actuating module controls the first linkage to rotate to separate the first casing from the main body so that the thermal dissipating module is exposed from the main body and the electronic device is switched from a closed state to an open state.

### CROSS-REFERENCE TO RELATED APPLICATION

This application claims the priority benefit of TW application serial no. 101107088, filed on Mar. 2, 2012. The entirety of the above-mentioned patent application is hereby incorporated via reference herein and made a part of specification.

### BACKGROUND OF THE INVENTION

1. Field of the Invention

The disclosure relates to an electronic device and, more particularly, to an electronic device with a removable casing.

2. Description of the Related Art

With the development of electronic technology, a central processing unit (CPU) of a computer is operated at high clock frequencies, or even over-clocking to have high processing speed to process data. Consequently, computers should consume more power and CPUs generate more heat.

### BRIEF SUMMARY OF THE INVENTION

An electronic device is provided. The electronic device includes a main body, an actuating module, a first linkage, a first casing and a thermal dissipating module. The actuating module is disposed in the main body. One side of the first linkage is connected with the actuating module. The first casing is connected with other side of the first linkage. One side of the thermal dissipating module is disposed at the main body and the other side of the thermal dissipating module is disposed at the first casing. The actuating module controls the first linkage to rotate to separate one side of the first casing from the main body to make the thermal dissipating module be exposed from the main body and make the electronic device switch from a closed state to an open state.

In one embodiment, when the electronic device is at the open state, one side of the first casing is separated from the main body to form a first gap between the first casing and the main body.

In one embodiment, the electronic device further includes a second linkage connected the main body and the first casing.

In one embodiment, the thermal dissipating module includes a frame and a fan. The fan is covered by the frame and the fan is a centrifugal fan.

In one embodiment, the electronic device further includes a second casing disposed at a top plate.

In one embodiment, when the electronic device is switched to the open state, one side of the second casing is separated from the main body so that a second gap is formed between the second casing and the main body.

In one embodiment, the electronic device further includes a third casing. The first casing and the third casing are disposed at the two sides of the main body respectively.

Furthermore, the electronic device can be at a closed state or an open state. When the electronic device is at the closed state, two sides of the first casing are connected with the main body. To switch the electronic device to the open state, the actuating module is controlled to rotate the first linkage connected with the first casing to drive the first casing, and then one side of the first casing is separated from the main body, and a first gap is formed between the first casing and the main body to increase the inlet air into the electronic device. Additionally, the thermal dissipating module is disposed between the first casing and the main body to increase the air flow, so that the electronic device has a better effect of thermal dissipating.

### BRIEF DESCRIPTION OF THE DRAWINGS

FIG. 1 is a schematic diagram showing an electronic device in a first embodiment;

FIG. 2 is a perspective diagram showing an electronic device in the first embodiment;

FIG. 3 is an exploded schematic diagram showing an actuating module in an embodiment;

FIG. 4 is a schematic diagram showing a main body, an actuating module, a first linkage and a second linkage in an embodiment;

FIG. 5A and FIG. 5B are top views of a first linkage and a second linkage driving the first casing in an embodiment;

FIG. 6 is a schematic diagram of part of an electronic device in the first embodiment;

FIG. 7 is a schematic diagram showing an electronic device at a closed state in the first embodiment;

FIG. 8 is a schematic diagram showing an electronic device at an open state in the first embodiment;

FIG. 9 and FIG. 10 are schematic diagrams showing a top plate of the main body and a second casing in the first embodiment;

FIG. 11 is a schematic diagram showing an electronic device at an open state in a second embodiment;

FIG. 12 is a schematic diagram showing an electronic device at an open state in the second embodiment; and

FIG. 13 is a schematic diagram showing an electronic device at a closed state in the second embodiment.

### DETAILED DESCRIPTION OF THE EMBODIMENTS

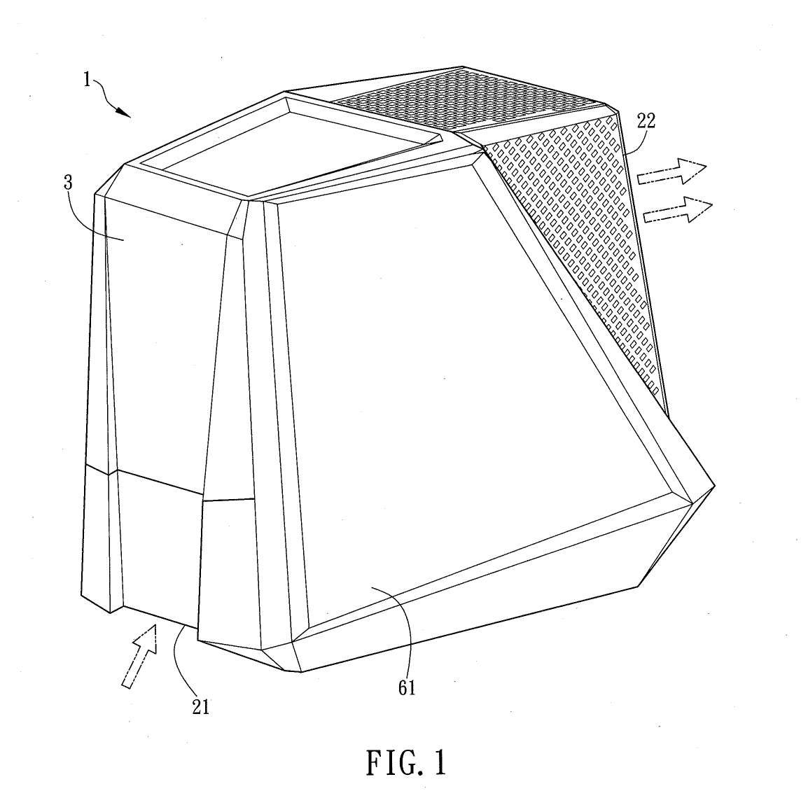

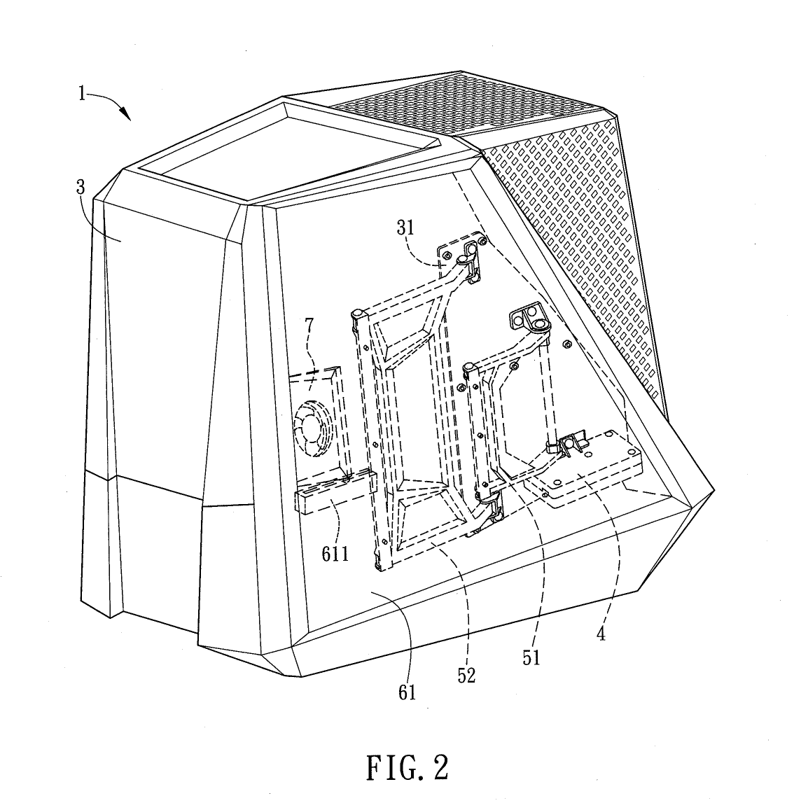

FIG. 1 is a schematic diagram of an electronic device in a first embodiment, and FIG. 2 is a perspective diagram of the electronic device in the first embodiment. In the first embodiment, a computer host is taken as an example of an electronic device 1, and the electronic device 1 includes a mainboard, a hard disk, a power supply and other electronic components, which is not limited herein. The electronic device 1 can be at a closed state or an open state. The electronic device 1 in FIG. 1 and FIG. 2 is at the closed state. The electronic device 1 at the closed state includes a first gap 21 and a second gap 22 to allow the air to flow into the electronic device 1 and help to dissipate heat of the electronic components inside the electronic device 1. The first gap 21 is at the bottom of the electronic device 1, and the second gap is at the rear of the electronic device 1, which is not limited herein.

Referring to FIG. 2, the electronic device 1 includes a main body 3, an actuating module 4 (such as a motor), a first linkage 51, a first casing 61 and a thermal dissipating module 7. The actuating module 4 and the first linkage 51 are disposed in the main body 3. In the first embodiment, the actuating module 4 and the first linkage 51 are disposed at a plate 31, which is not limited herein, the actuating module 4 and the first linkage 51 also can be disposed at a back plate, a top plate, a bottom plate and so on. The first linkage 51 is connected with the main body 3, the actuating module 4 and the first casing 61, respectively. Moreover, the electronic device 1 in the first embodiment further includes a second linkage 52 to connect the main body 3 with the first casing 61 steadily. The first casing 61 is disposed at one side of the main body 3. The thermal dissipating module 7 is connected with the main body 3 and the first casing 61 respectively. When the electronic device 1 is at the closed state, two sides of the first casing 61 are connected with the main body 3, respectively, and the thermal dissipating module 7 is held in the main body 3.

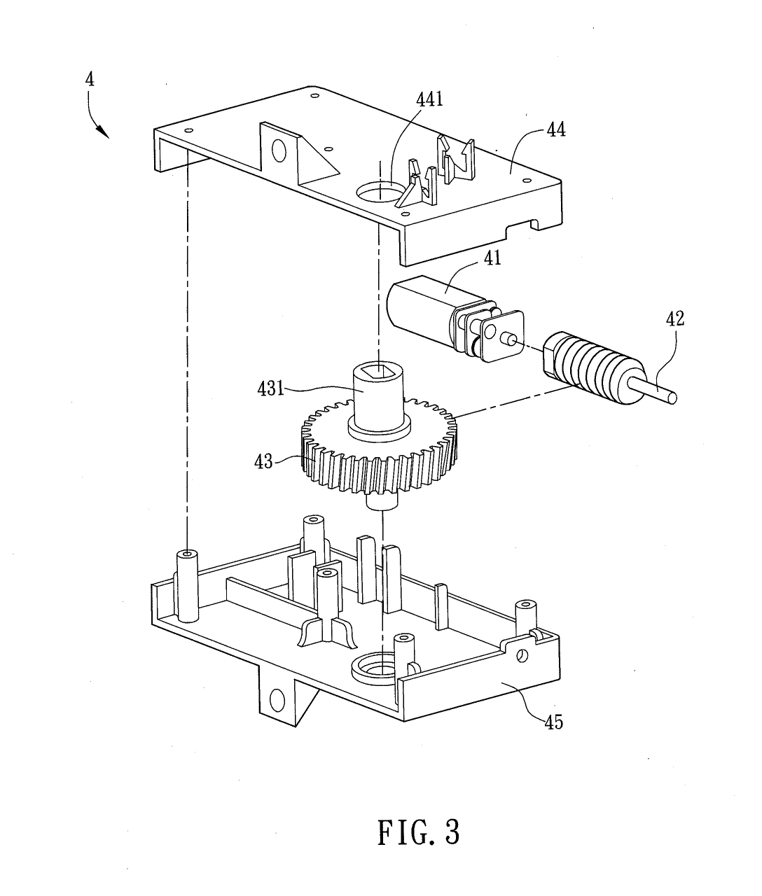

FIG. 3 is an exploded schematic diagram showing an actuating module in an embodiment. The actuating module 4 includes a linear motor 41, a worm 42, a turbine 43, a top cover 44 and a bottom cover 45. The liner motor 41 is connected with the worm 42, and the worm 42 is connected with the turbine 43. When the linear motor 41 drives the worm 42 to rotate, the worm 42 drives the turbine 43 to rotate simultaneously. Moreover, the top cover 44 is connected with the bottom cover 45, and an accommodating space is formed therebetween. The linear motor 41, the worm 42 and the turbine 43 are disposed in the accommodating space. The top cover 44 includes an opening 441 to allow a central shaft 431 of the turbine 43 passing through the top cover 44.

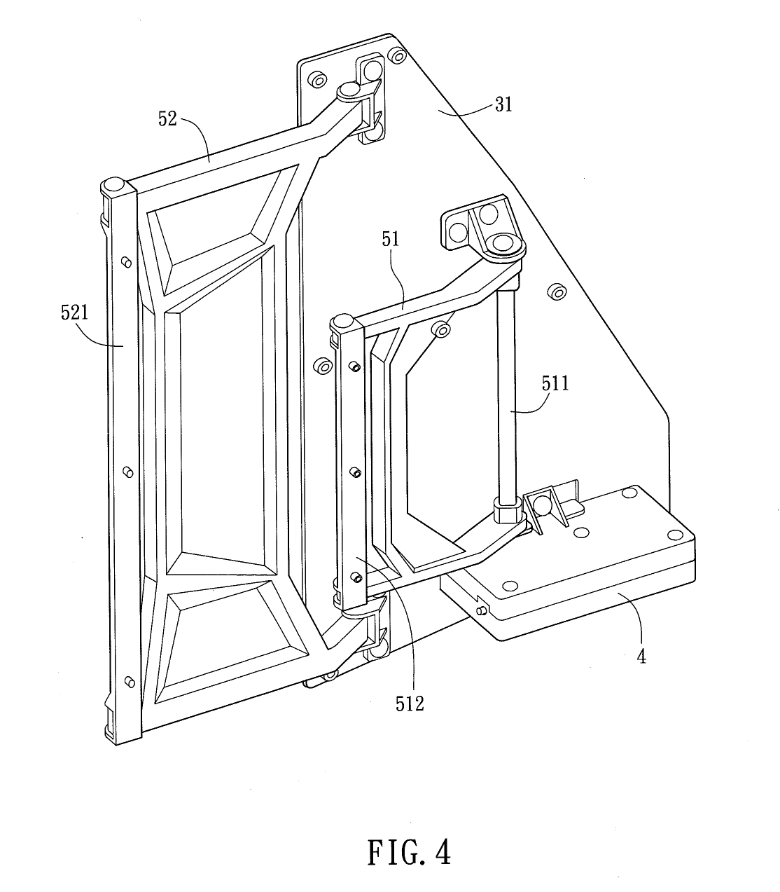

FIG. 4 is a schematic diagram showing a main body, an actuating module, a first linkage and a second linkage in an embodiment. The first linkage 51 includes a first bracket 511 and a second bracket 512. One end of the first bracket 511 of the first linkage 51 is fixed on the plate 31 of the main body 3, and the other end of the first linkage 511 is fixed on the central shaft 431 of the turbine 43. The second bracket 512 of the first linkage 51 is disposed at and connected with the first casing 61. The second linkage 52 includes a third bracket 521. One side of the second linkage 52 is disposed at the plate 31 of the main body 3, and the other side of the second linkage 52 with the third bracket 521 is connected with the first casing 61.

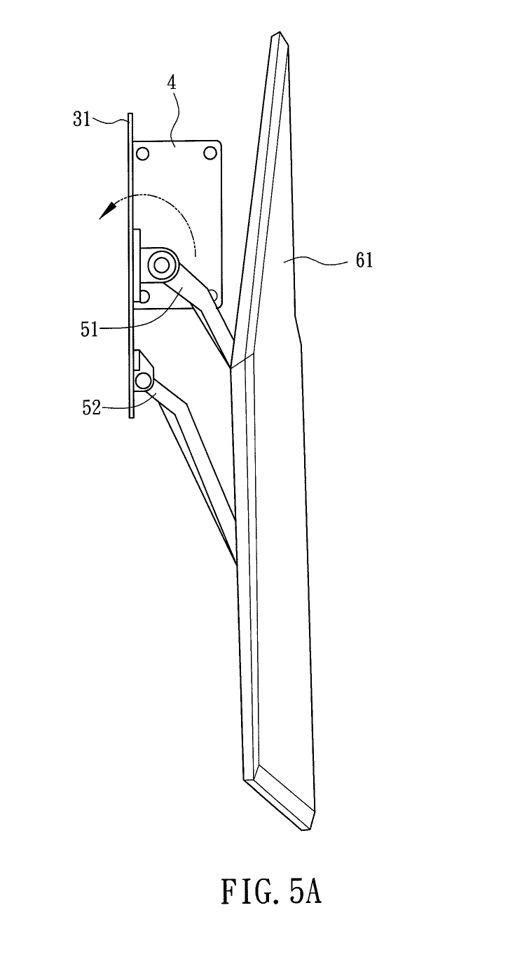

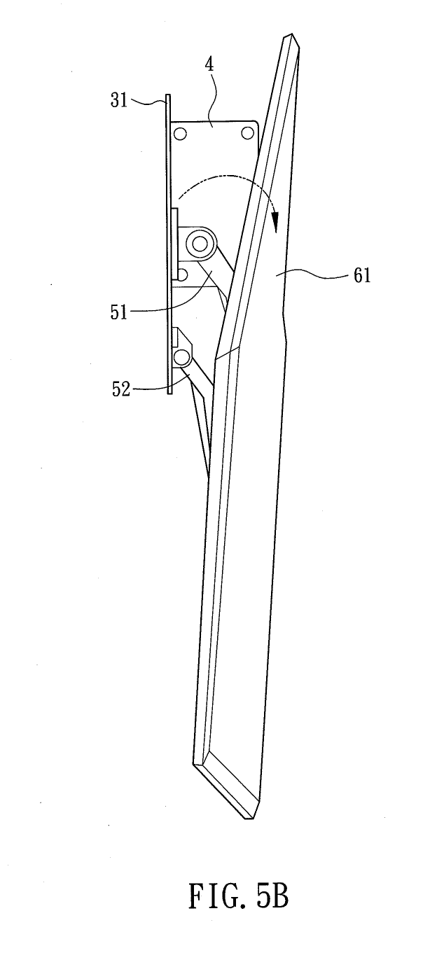

FIG. 5A and FIG. 5B are top views of the first linkage 51 and the second linkage 52 driving the first casing 61. FIG. 6 is a schematic diagram of part of the electronic device 1 in the first embodiment. Referring to FIG. 3, FIG. 4, FIG. 5A, FIG. 5B and FIG. 6, when the liner motor 41 drives the worm 42 and the turbine 43 to rotate, since the first bracket 511 of the first linkage 51 is connected with the turbine 43, the first linkage 51 rotates along with the turbine 43. Since the second bracket 512 of the first linkage 51 and the third bracket 521 of the second linkage 52 are connected with the first casing 61, when the first linkage 51 rotates to move the first casing 61, the second linkage 52 also rotates and provides assistant force to move the first casing 61. In the first embodiment, the size of the second linkage 52 is bigger than that of the first linkage 51, and the shape of the first linkage 51 is different from that of the second linkage 52. However, the size and the shape of the first linkage 51 and the second linkage 52 are not limited herein, and they can be various according to the requirements.

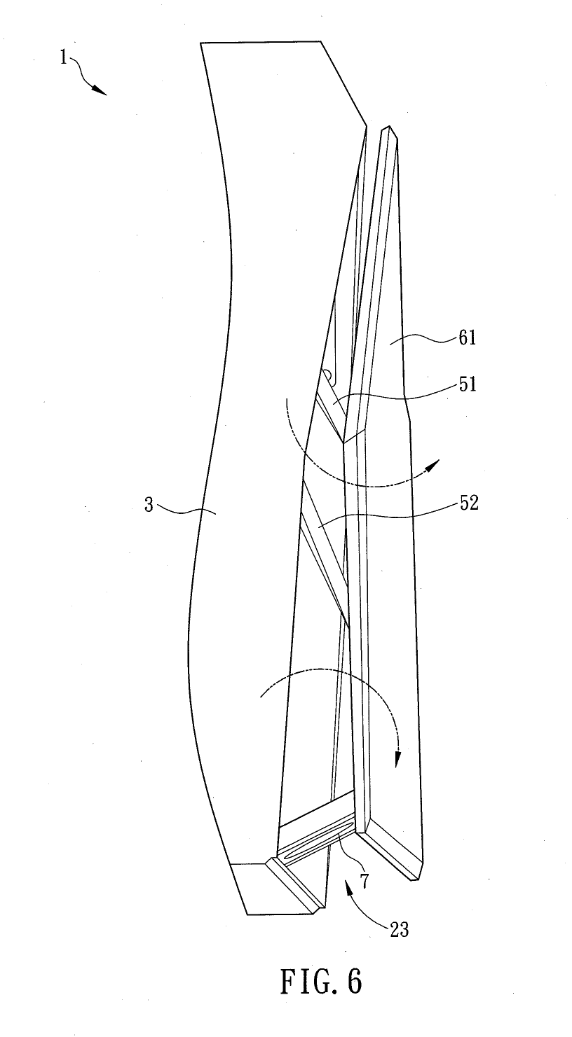

FIG. 7 is a schematic diagram showing the electronic device 1 at the closed state in the first embodiment. The first casing 61 includes a guide rail 611. One side of the thermal dissipating module 7 is disposed at the main body 3, and the other side of the thermal dissipating module 7 is disposed at the guide rail 611 of the first casing 61. The thermal dissipating module 7 includes a frame 71 and a fan 72. The frame 71 covers the fan 72 and is connected with the frame 71. The fan 72 in the first embodiment is a centrifugal fan, which is not limited herein. The type of the fan 72 can be changed according to the position of the thermal dissipating module 7 or the shape and the size of the electronic device 1, such as a tube-axial fan, an oblique flow fan, or a cross-flow fan. When the electronic device 1 is at the closed state, the thermal dissipating module 7 is accommodated in the main body 3. When the electronic device 1 is at the open state, the first casing 61 is separated from the main body 3 due to the push of the first linkage 51 and the second linkage 52, and thus the thermal dissipating module 7 moves on the guide rail 611 and is exposed from the main body 3.

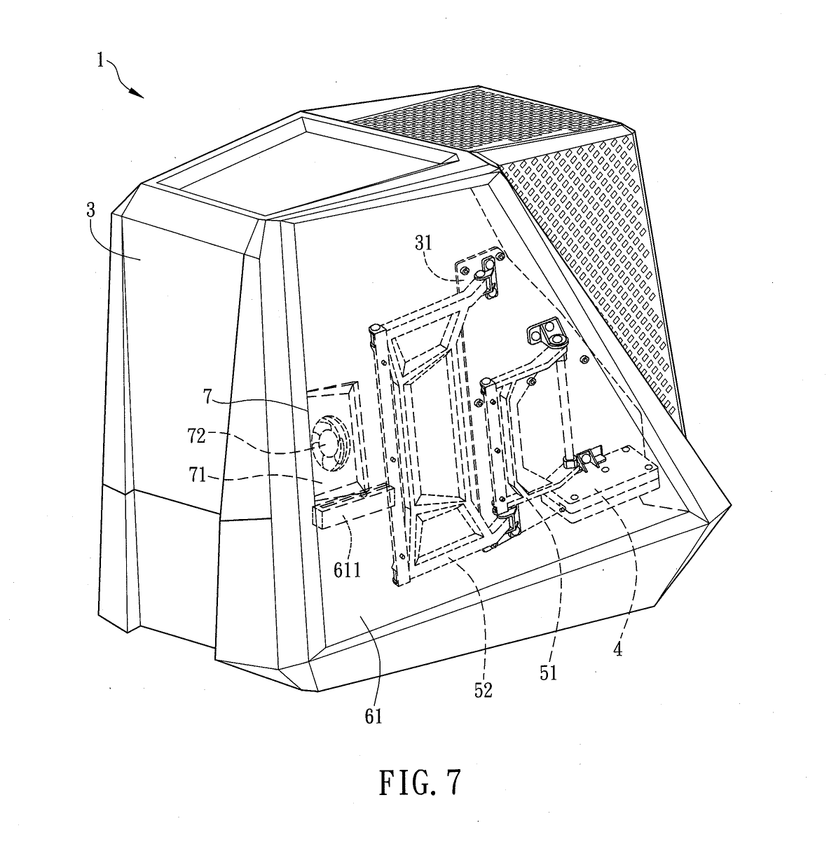

As shown in FIG. 7 and FIG. 8. FIG. 8 is a schematic diagram showing the electronic device 1 at the open state. When the temperature inside the electronic device 1 is high or the electronic components inside the electronic device 1 is over clocked, the electronic device 1 can be switched from the closed state to the open state manually or by the control of the electronic components inside the electronic device 1. In the embodiment, the closed state is the state that the first casing 61 is closely connected with the main body 3. The open state can be the state that at least one side of the first casing 61 is separated from the main body 3 and a first gap 23 is formed between the first casing 61 and main body 3, and thus the external air not only flows from the first gap 23 at the bottom of the electronic device 1, but also flows from the first gap 23 between the first casing 61 and the main body 3 into the electronic device 1. Consequently, the volume of the air flowing into the electronic device 1 is increased to enhance the thermal dissipation effect so as to decrease the temperature. Moreover, when the electronic device 1 is switched to the open state, the thermal dissipating module 7 moves on the guide rail 611 of the first casing 61, and the thermal dissipating module 7 is exposed from the main body 3 and faces to the first gap 23 to guide the air to flow into the electronic device 1, and then the flow of the air is increased, and the volume of the air flowing into the electronic device 1 is increased.

Furthermore, in an embodiment, when the electronic device 1 is switched from the closed state to the open state in an automatic way, the electronic device 1 may further include a detecting module (not shown).The detecting module is connected with the actuating module 4 or other electronic components in the electronic device 1. The detecting module detects the temperature inside the electronic device 1. When the temperature is higher than a limited value, the detecting module transmits a signal to start and control the actuating module 4 to separate the first casing 61 from the main body 3. The electronic device 1 is switched to the open state to increase the volume of the air into the electronic device and the heat dissipation effect is enhanced. Correspondingly, when the temperature inside the electronic device 1 is lower than a limited value, the detecting module transmits another signal to the actuating module 4 to actuate the first casing 61 to return to be connected with the main body 3, so that the electronic device 1 is switched from the open state to the closed state. The electronic device 1 can control the actuating module 4 to start by software or hardware, so that the electronic device 1 can be switched between the closed state and open state.

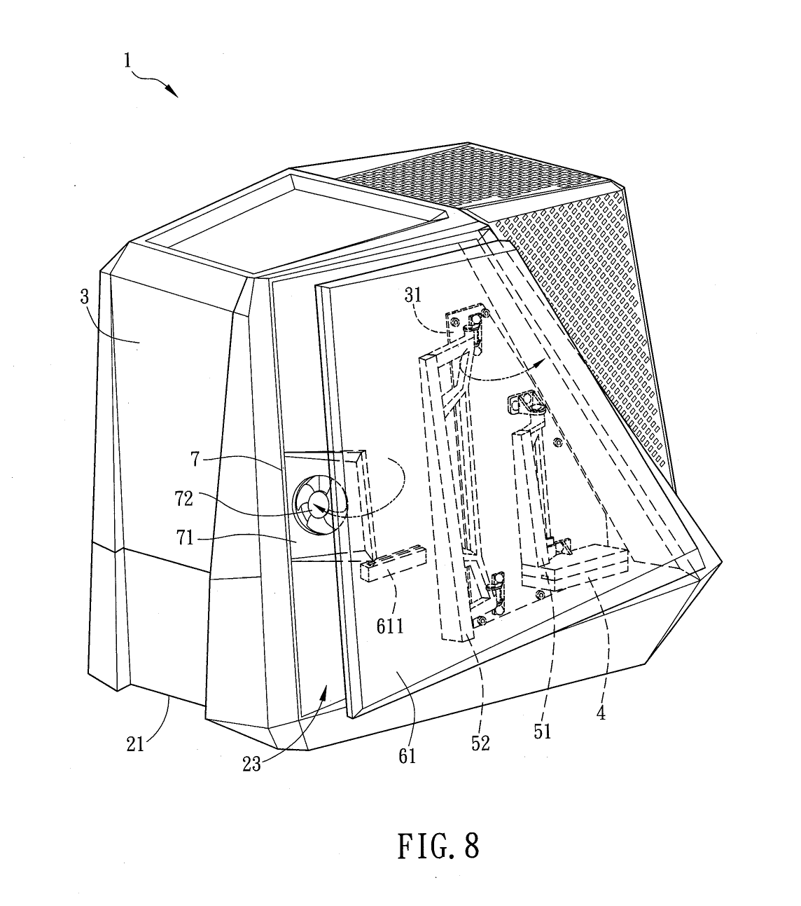

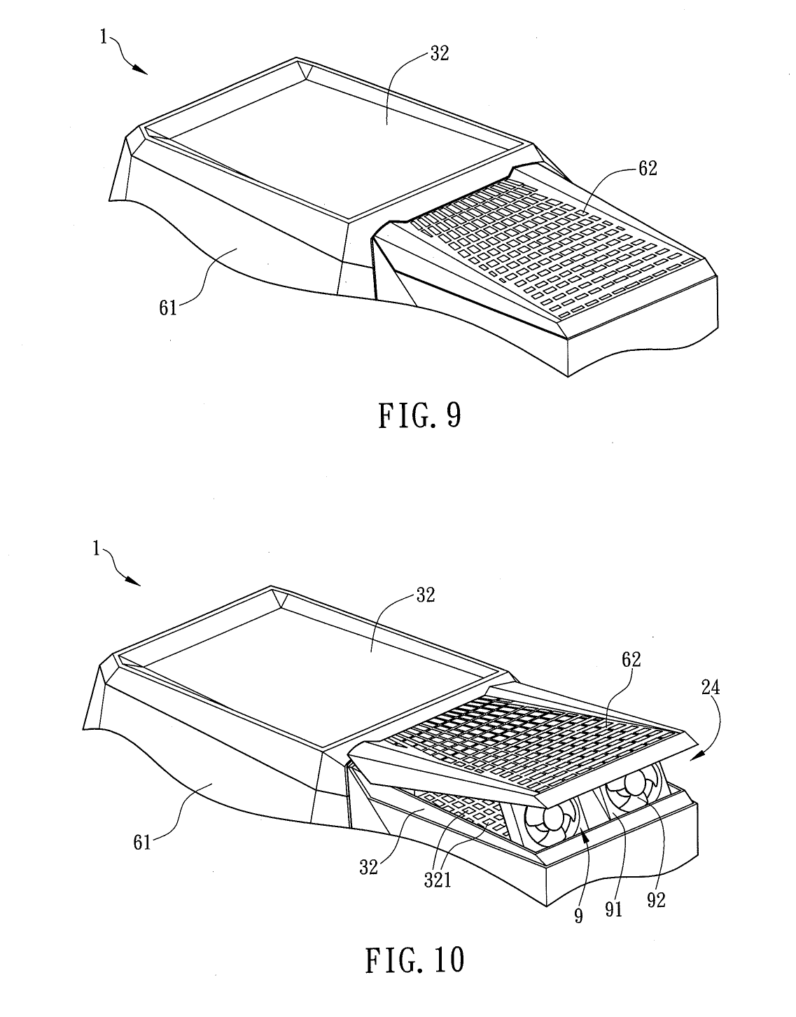

FIG. 9 and FIG. 10 are schematic diagrams showing a top plate of the main body and a second casing in the first embodiment. The main body 3 further includes a top plate 32, and the top plate 32 includes a plurality of opening holes 321.

The electronic device 1 further includes a second casing 62 and a thermal dissipating module 9. The second casing 62 is disposed on the top plate 32 corresponding to the opening holes 321, and one end of the second casing 62 is connected with the top plate 32. The second casing 62 includes a guide rail (not shown). The thermal dissipating module 9 is connected with the second casing 62 and the top plate 32, and one end of the thermal dissipating 9 is disposed on the guide rail of the second casing 62. The electronic device 1 includes two thermal dissipating modules 9 in this embodiment, which is not limited herein. The thermal dissipating module 9 includes a frame 91 and a fan 92. The frame 91 covers the fan 92 and is connected with the fan 92. The fan 92 is a centrifugal fan in the embodiment, which is not limited herein.

In one embodiment, when the electronic device 1 is switched from the closed state to the open state, one side of the second casing 62 is separated from the top plate 32 and a second gap 24 is formed between the second casing 62 and the main body 3. Consequently, the air in the electronic device 1 can be exhausted not only from the second gap 22 at the rear of the electronic device 1 but also from the second gap 24 between the second casing 62 and the main body 3, and thus the volume of the air out the electronic device 1 is increased. Furthermore, when the electronic device 1 is switched to the open state, the thermal dissipating module 9 moves on the rail of the second casing 62, and the thermal dissipating module 9 is exposed from the main body 3 and faces to the second gap 24. By guiding the air to flow out of the electronic device 1, the volume of air out the electronic device is increased, and the effect of thermal dissipation inside the electronic device 1 is enhanced. The mechanisms and principles of controlling the movement of the second casing 62 are same to those of the first casing 61, which is omitted herein.

In the first embodiment, to enhance the thermal dissipating efficiency of the electronic device 1, the electronic device 1 can be switched from the closed state to the open state manually or via the electronic components inside the electronic device 1. Not only the first casing 61 can be controlled to move to make at least one side of the casing 61 separated from the main body 3 to increase the inlet air, the second casing 62 also can be controlled to separate from the main body 3 to increase the volume of the air into the electronic device 1 to further increase the outlet air and bring the heat generated by the electronic components inside the electronic device 1 out. Furthermore, the actuating module 4 can control the first casing 61 and the second casing 62 simultaneously or separately to adjust the inlet air and the outlet air.

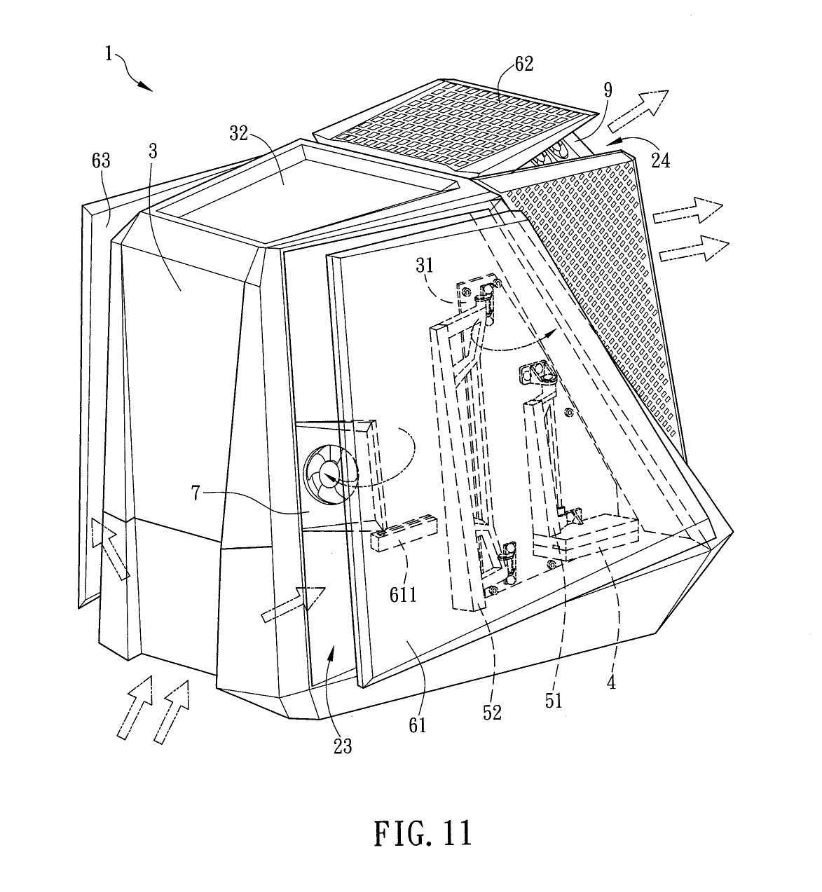

FIG. 11 is a schematic diagram showing an electronic device at the open state in a second embodiment. The electronic device 1 further includes a third casing 63. The first casing 61 and the third casing 63 are disposed at two sides of the main body 3, respectively. Similarly, the third casing 63 includes mechanisms of controlling the first casing 61 to move, such as the actuating module 4, a plurality of linkages 51 and 52, and a plurality of thermal dissipating modules 7 to improve the inlet air of the electronic device 1, so as to improve the thermal dissipation effect of the electronic device 1. The numbers of the actuating module 4, the linkage 51,52 and the thermal dissipating module 7 may be various according to different requirements such as the size of the electronic device 1, the effect of thermal dissipation, the cost of production, which are not limited herein. Furthermore, the actuating module 4 can control the first casing 61 and the third casing 63 simultaneously or separately, so that the volume of the air into the electronic device 1 can be controlled. For example, the actuating module 4 can be used to control the movement of the first casing 61, but not control the movement of the third casing 63 to make the main body 3 and the main body 3 keep in the closed state.

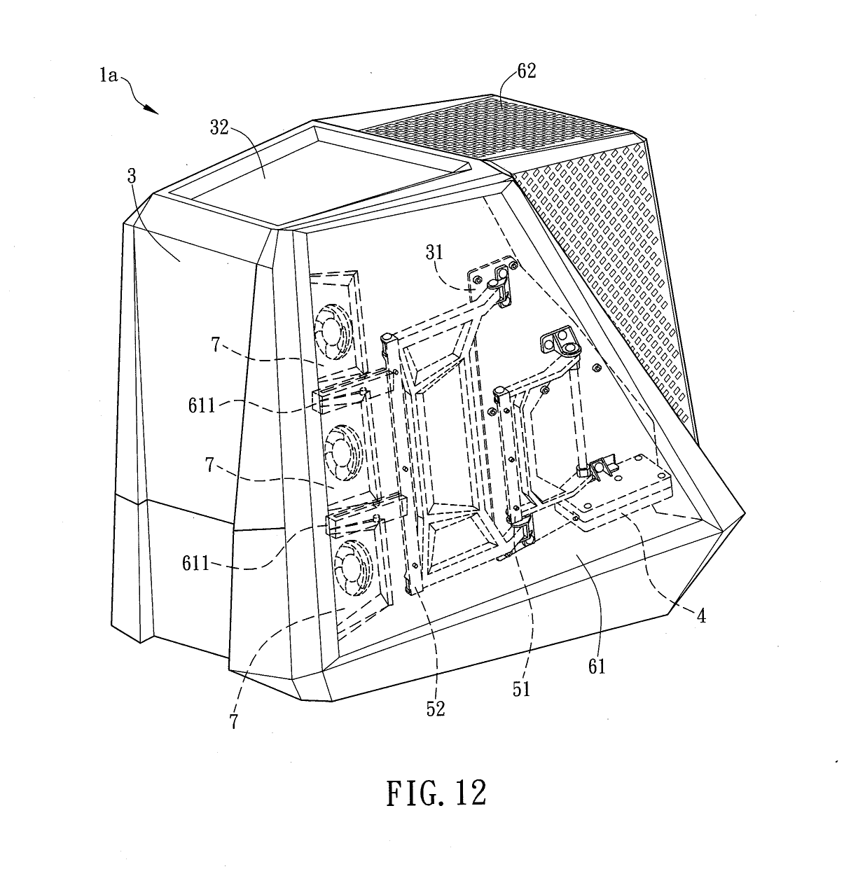

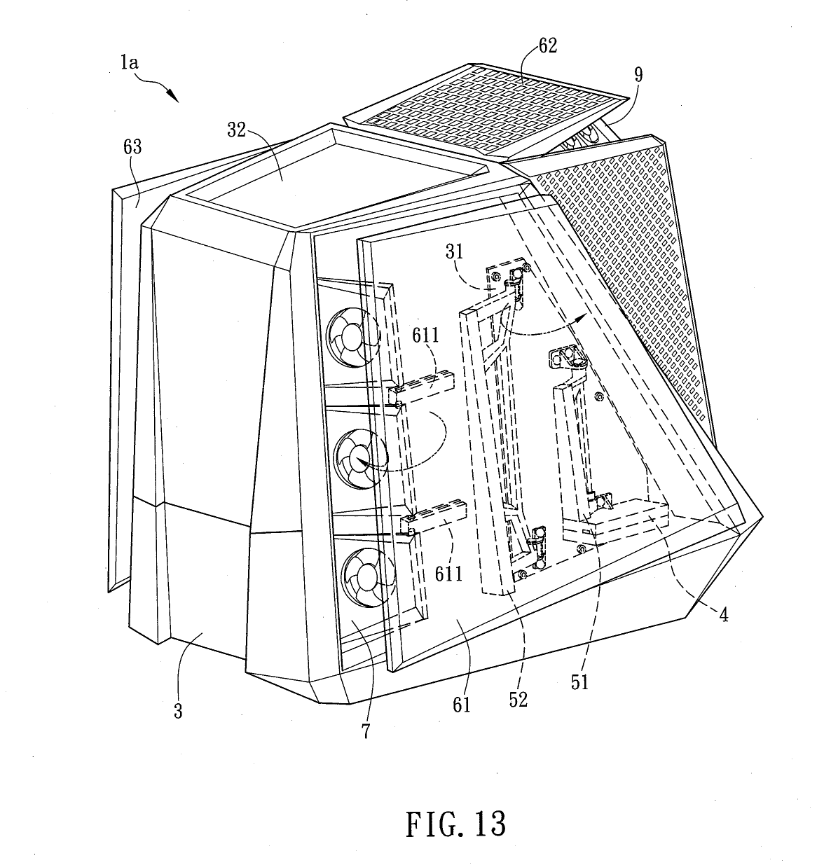

FIG. 12 and FIG. 13 are schematic diagrams showing an electronic device 1a in a second embodiment. The electronic device 1a includes a plurality of thermal dissipating modules 7 and 9. Three thermal dissipating modules 7 are disposed at one side of the main body 3. The thermal dissipating module 7 is connected with the first casing 61 and the main body 3 respectively, and the thermal dissipating modules 7 can moves on the guide rail 611 of the first casing 61. When the electronic device 1a is switched to the closed state, the thermal dissipating module 7 is disposed in the main body 3. When the electronic device 1a is switched to the open state, the thermal dissipating module 7 moves on the guide rail 611 and is exposed from the main body 3. Moreover, the thermal dissipating module 9 is connected with the second casing 62 and the main body 3 to enhance volume of the air flow and guide the air. As a result, the inlet air and the outlet air are increased, and the electronic device 1a has better heat dissipation effect. The electronic device 1a can further includes a plurality of thermal dissipating modules connected with the third casing 63 and the main body 3 to increase the volume of air into the electronic device 1a.

To sum up, the electronic device can be at a closed state or an open state. When the electronic device is at the closed state, two sides of the first casing are connected with the main body. To switch the electronic device to the open state, the actuating module is controlled to rotate the first linkage connected with the first casing to drive the first casing, and then one side of the first casing is separated from the main body, and a first gap is formed between the first casing and the main body to increase the volume of the inlet air into the electronic device. Additionally, the thermal dissipating module is disposed between the first casing and the main body to increase the air flow, so that the electronic device has a better effect of thermal dissipation.

Although the disclosure has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. An electronic device, comprising:
a main body;
an actuating module disposed in the main body;
a first linkage, wherein one side of the first linkage is connected with the actuating module;
a first casing connected with other side of the first linkage; and
a thermal dissipating module, wherein one side of the thermal dissipating module is disposed at the main body, and the other side of the thermal dissipating module is disposed at the first casing;
wherein the actuating module controls the first linkage to rotate to separate one side of the first casing from the main body to make the thermal dissipating module exposed from the main body and make the electronic device switch from an open state to a closed state.

2. The electronic device according to claim 1, wherein when the electronic device is at the open state, one side of the first casing is separated from the main body to form a gap between the first casing and the main body.

3. The electronic device according to claim 1, further comprising a second linkage connected the main body and the first casing.

4. The electronic device according to claim 1, wherein the thermal dissipating module includes a frame and a fan, and the frame covers the fan.

5. The electronic device according to claim 4, wherein the fan is a centrifugal fan.

6. The electronic device according to claim 1, further comprising a second casing disposed at a top plate of the main body.

7. The electronic device according to claim 6, wherein when the electronic device is switched to the open state, one side of the second casing is separated from the main body, and a second gap is formed between the second casing and the main body.

8. The electronic device according to claim 1, further comprising a third casing, wherein the first casing and the third casing are disposed at two sides of the main body, respectively.
